(19) United States
(12) Patent Application Publication
(10) Pub. No.: US 2013/0344632 A1
(43) Pub. Date: Dec. 26, 2013

(54) Thermal Management Within an LED Assembly

(71) Applicants: Gregory Becker, Sanford, MI (US); Dorab Bhagwagar, Saginaw, MI (US); Andrew Lovell, Midland, MI (US); Michael Strong, Midland, MI (US)

(72) Inventors: Gregory Becker, Sanford, MI (US); Dorab Bhagwagar, Saginaw, MI (US); Andrew Lovell, Midland, MI (US); Michael Strong, Midland, MI (US)

(73) Assignee: Dow Corning Corporation, Midway, MI (US)

(21) Appl. No.: 14/003,828

(22) PCT Filed: Feb. 20, 2012
(86) PCT No.: PCT/US12/25781

§ 371 Date: Sep. 9, 2013

Related U.S. Application Data
(60) Provisional application No. 61/466,231, filed on Mar. 22, 2011.

(51) Int. Cl. H01L 31/024

(52) U.S. Cl. CPC H01L 31/024
USPC 438/26

(57) ABSTRACT

This invention is directed to a method for applying a thermal management composition between an LED mounted circuit board and a heat sink, comprising the steps of; (a) applying a deposit of a thermal management composition onto either a second surface of the LED mounted circuit board or onto a surface of a heat sink, through a deposition tool the deposition tool having at least one aperture (401) where the at least one aperture has a perimeter surrounded by sidewalls, where the sidewalls have heights, where the heights are reduced around at least a portion (402) of the perimeter of the apertures on the deposition tool as compared to the average height of the deposition tool and (b) securing the LED mounted circuit board and the heat sink.

### CROSS REFERENCE TO RELATED APPLICATIONS

This application claims the benefit of U.S. Provisional Patent Application Ser. No. 61/466,231, filed on 22 Mar. 2011, under 35 U.S.C. §119(e). U.S. Provisional Patent Application Ser. No. 61/466,231 is hereby incorporated by reference.

### BACKGROUND OF THE INVENTION

This invention relates to the thermal management of light emitting diode (LED) based lighting systems.

With higher power LED applications, thermal management is becoming a critical issue. Without adequate thermal management, the temperature of an LED package can rise significantly. This rise in temperature can cause changes in the output wavelength of light, yellowing of lens, breaking of wire bonds, delamination, and internal solder joint detachment. The final outcome may be a catastrophic failure of the LED device.

There are three mechanisms for dissipating thermal energy from an LED: conduction, radiation, and convection. Conduction occurs when LED chips, the mechanical structure of the LEDs, the LED mounting structure (such as printed circuit boards), and the light fixture housing are placed in physical contact with one another. Physical contact with the LED is generally optimized to provide electrical power and mechanical support. Traditional means of providing electrical and mechanical contact between LEDs and the light fixture provide poor means of conduction between the LEDs and external light fixture surfaces (such as die cast housing). One disadvantage of using a thermally conductive structure within the light fixture envelope is that it allows dissipation of heat into the enclosure, which is generally sealed. This effectively raises the ambient temperature of the air surrounding the LEDs, thus compounding thermal related failures.

Radiation is the movement of energy from one point to another via electromagnetic propagation. Much of the radiant energy escapes the light fixture through the clear optical elements (light emitting zones, lenses, etc) and reflectors, which are designed to redirect the radiant energy (visible light in particular) out of the light fixture according to the needs of the application. The radiant energy that does not escape through the lenses is absorbed by the various materials within the light fixture and converted into heat.

Convection occurs at any surface exposed to air, but may be limited by the amount of air movement near the emitting surface, the surface area available for dissipation, and the difference between the temperature of the emitting surface and the surrounding air. In many cases, the light fixture is enclosed further restricting airflow around the LEDs. In the case of an enclosed light fixture, heat generated by the LEDs is transferred by convection to the air within the enclosure, but cannot escape the boundaries of the enclosure. As a result, the air within the enclosure experiences a build up of heat, which elevates lamp and light fixture temperatures and may lead to heat related failures.

Heat transfer between the LED board and the heat sink is through a fabricated thermal interface pad. Conventional heat sinks are often formed, or stamped from metals including copper and aluminum, in an array of shapes. Normally they have a flat surface or recessed cavity into which the LED board is attached. Prior to attaching the heat sink, a die cut fabricated thermal pad is placed between the heat sink and the LED board.

This invention pertains to a novel method of thermal management of the LED package. Instead of using a fabricated thermal pad, a thin layer of curable thermal management composition is printed or dispensed directly on the LED board or the heat sink. The thermal management composition can either (1) be pre-cured on the LED board or the heat sink with a room or low temperature cure prior to attaching the LED board and the heat sink or (2) attached to either the LED board or heat sink, followed by attaching the LED board and heat sink and cured over time in between the LED board and the heat sink.

### SUMMARY OF THE INVENTION

This invention is directed to a method for applying a thermal management composition between an LED mounted circuit board and a heat sink, where the LED mounted circuit board comprises a substrate having a first surface with at least one LED mounted thereto and a second surface opposite the first surface, the method comprising the steps of;

(a) applying a deposit of a thermal management composition onto either the second surface of the LED mounted circuit board or onto a surface of the heat sink, through a deposition tool having at least one aperture, where the at least one aperture has a perimeter surrounded by sidewalls, where the sidewalls have heights, where the heights are reduced around at least a portion of the perimeter of the apertures on the deposition tool as compared to the average height of the deposition tool and

(b) securing the LED mounted circuit board and the heat sink wherein the thermal management composition resides between the second surface of the LED mounted circuit board and the surface of the heat sink.

In one embodiment, the thermal management composition is cured after step (b) and in another embodiment, the thermal management composition is cured before step (b).

### DESCRIPTION OF THE DRAWINGS

FIG. 1 is a schematic view of a LED mounted circuit board, a thermal management composition, and a heat sink prior to assembly, according to the present invention;

FIG. 2 is a view of a LED mounted circuit board.

FIG. 3 is a view of a heat sink.

FIG. 4a shows a top view of a down-step stencil useful in the method of this invention.

FIG. 4b shows a top view of a portion of the stencil in FIG. 4a.

FIG. 4c is a side cross sectional view taken along line A of the portion of the stencil in FIG. 4b.

FIG. 4d is a side cross sectional view taken along line B of the portion of the stencil in FIG. 4b.

### DETAILED DESCRIPTION OF THE INVENTION

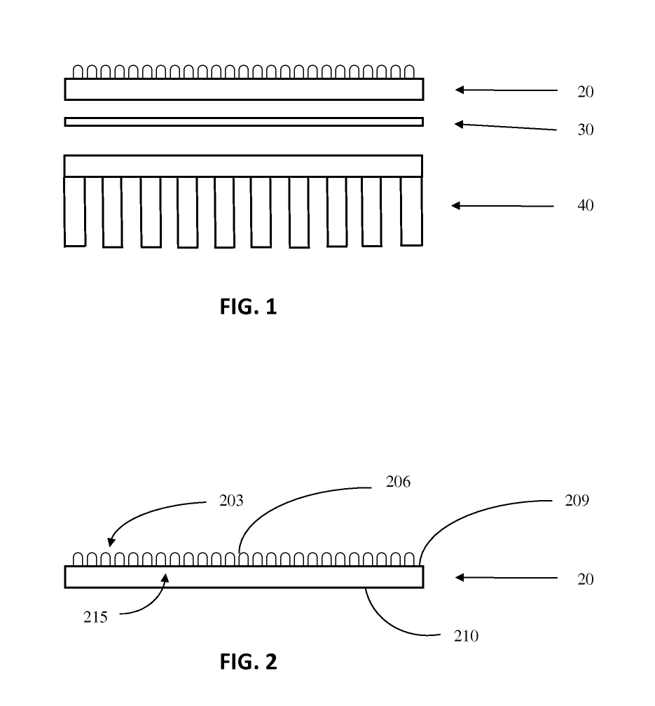

With reference to FIG. 1, a thermal management composition in the form of a film or layer 30 provides a thermal interface between a LED mounted circuit board 20 and a heat sink 40, such as a block of heat transmissive material, to facilitate heat transfer from the LED mounted circuit board 20 to the heat sink 40. It will be appreciated that the LED mounted circuit board generates excess heat in its operation, which heat if not removed, may damage or impair operation of the LED mounted circuit board.

The film 30 is from about 0.1 to 1 millimeter or from about 0.15 to 0.3 millimeters in thickness. The film thickness can be further increased, if desired, to accommodate certain application requirements, such as larger spacing characteristics in electronics or power supply cooling application.

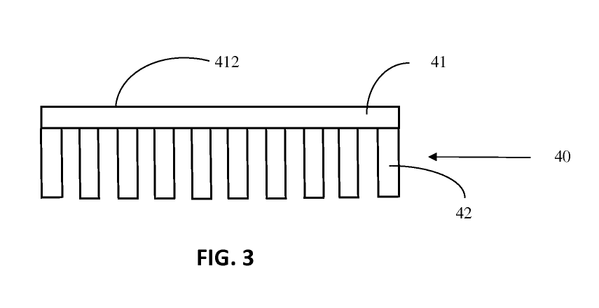

As shown in FIG. 2, within 20, a LED array 203 that include a plurality of LEDs 206 is present on a top surface 209 of a thin substrate 215, having a bottom surface 210. The substrate 215 is planar or of a non-planar surface. The LEDs 206 may be present as a random placement, as a matrix, or as a well defined pattern, that defines letters, symbols, or figures. Regardless of the LED array 203, when assembled, each LED 206 is attached to the top surface 209 of the substrate 215 and is electrically connected with terminals. The terminals are used for electrically connecting with the LEDs 206 to supply current to the LED mounted circuit board 20.

The substrate 215 is a metal core printed circuit board (MCPCB). To form the MCPCB, a planar-shaped metal plate which is made of aluminum (Al) is used. Alternatively, the metal plate can be made of other materials having higher heat conductivity, such as copper (Cu) or its alloys. Then an insulating layer is formed on the outer surface of the metal plate. The insulating layer is then coated with a copper foil layer through sputtering, hot-press, electroless copper deposition or electrodeposition. Finally the sets of electrical circuitry are formed by photoresist coating, exposing and etching the copper foil layer. It is to be understood that the substrate 215 can be other kinds of printed circuit boards, such as metal base printed boards, ceramic substrate printed boards and so on.

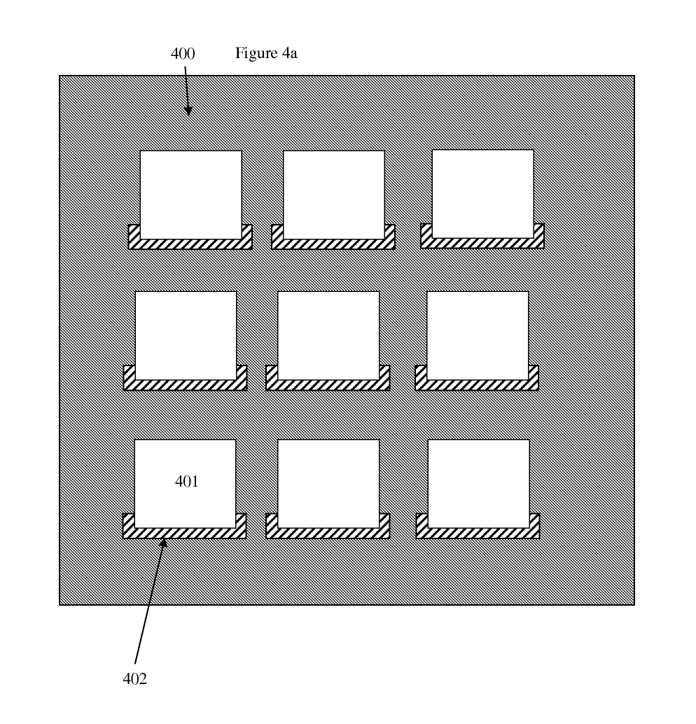

The heat sink 40, shown in FIG. 3, is arranged under the thermal management composition 30. The heat sink 40 as shown in this embodiment is an extruded aluminum fin-type heat sink. Alternatively, the heat sink 40 can be a plate-type heat pipe or a vapor chamber which has a relatively high heat transfer capability due to the phase change mechanism used. Also the heat sink 40 can be a cold plate in which a flow channel is defined for passage of working fluid. Also the heat sink 40 can be made of a highly thermally conductive material, such as copper or its alloys. The heat sink 40 includes a chassis 41 and a plurality of pin fins 42 extending downwardly from the chassis 41. The fins 42 are used for increasing the heat dissipation area of the heat sink 40. Alternatively, the fins 42 can be flat shaped. The fins 42 and the chassis 41 can be formed separately, and then connected together by soldering. The chassis 41 of the heat sink 40 has a top surface that becomes attached to the thermal management composition 30. Alternatively, the heat sink 40 can be a plate-type heat pipe or a vapor chamber which has a relatively high heat transfer capability due to the phase change mechanism used. Also the heat sink 40 can be a cold plate in which a flow channel is defined for passage of working fluid. Also the heat sink 40 can be made of a highly thermally conductive material, such as copper or its alloys.

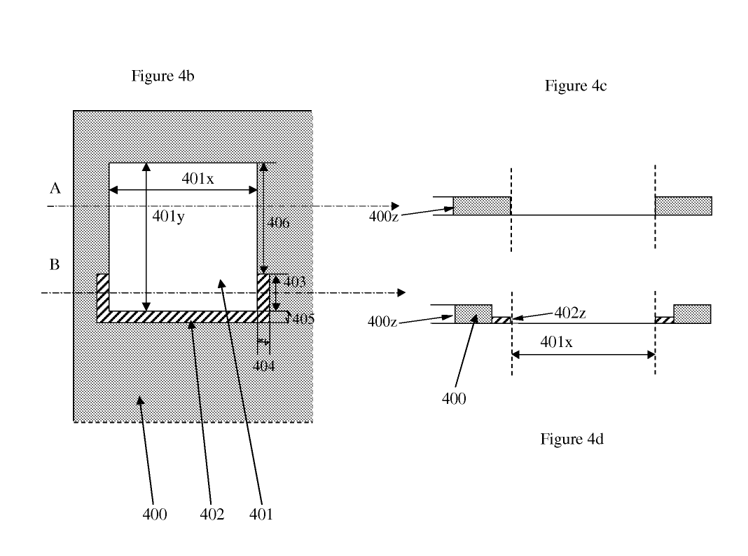

The thermal management composition may be applied to either the bottom surface 210 of the LED mounted circuit board or onto the top surface 412 of the heat sink, by forcing the composition through a deposition tool having at least one aperture surrounded by sidewalls. The heights of the sidewalls are reduced around at least a portion of the perimeter of the apertures on the deposition tool as compared to the average height of the deposition tool. For example, the thermal management composition may be applied onto the bottom surface of the LED mounted circuit board or onto a surface of the heat sink, by processes such as printing. Examples of suitable printing processes include stencil printing using a deposition tool exemplified by a down-step stencil and screen printing using a deposition tool exemplified by a screen having a plurality of apertures, each aperture being surrounded by sidewalls. The heights of the sidewalls are reduced around at least a portion of the perimeter of each aperture on the screen as compared to the average thickness of the screen. An example of a suitable down-step stencil is shown in FIGS. 4a, 4b, 4c, and 4d. FIG. 4a shows a top view of the down-step stencil 400 including a plurality of square apertures 401. Each aperture 401 has an etched area 402 around the trailing edge. The etched area 402 has a height 402z less than the height 400z of the remainder of the stencil 400. One skilled in the art would recognize that the exact stencil configuration selected depends on various factors including the composition selected to form the flat-top deposit and the size and shape of the flat-top deposit desired. The stencil may have apertures with square corners as shown in FIG. 4a or apertures with rounded corners. The stencil may alternatively have an etched area surrounding the entire perimeter of each aperture. The stencil may optionally be electropolished.

The thermal management composition, once deposited may be hardened by any convenient means, such as by curing. A suitable curable silicone composition is a hydrosilylation or peroxide curable silicone composition comprising:

(A) a polyorganosiloxane base polymer having an average per molecule of at least two aliphatically unsaturated organic groups,

optionally (B) a crosslinker having an average per molecule of at least two silicon bonded hydrogen atoms,

(C) a catalyst selected from hydrosilylation reaction catalyst and peroxide cure catalysts,

(D) a thermally conductive filler, and optionally

(E) an organic plasticizer soluble in ingredient (A), which does not inhibit curing of the composition.

The thermal management composition may be curable, for example, by hydrosilylation or peroxide cure. In the hydrosilylation curable composition, ingredient (B) is present. In the peroxide curable composition, ingredient (B) is optional.

### Hydrosilylation Curable Composition

The hydrosilylation curable composition may comprise: 100 parts by weight of (A′) a polyorganosiloxane base polymer having an average per molecule of at least two aliphatically unsaturated organic groups; (B′) a crosslinker, such as a silane or siloxane, having an average per molecule of at least two silicon bonded hydrogen atoms; and an amount sufficient to initiate curing of the composition of (C′) a platinum group metal catalyst, where the ingredients and amounts may be selected such that a cured silicone prepared by curing the composition is a silicone rubber.

### Ingredient (A′) Base Polymer

Ingredient (A′) of the hydrosilylation curable composition may comprise a polyorganosiloxane having an average of at least two aliphatically unsaturated organic groups per molecule. Ingredient (A′) may have a linear or branched structure. Ingredient (A′) may be a homopolymer or a copolymer. The aliphatically unsaturated organic groups may be alkenyl exemplified by, but not limited to, vinyl, allyl, butenyl, and hexenyl. The unsaturated organic groups may be alkynyl groups exemplified by, but not limited to, ethynyl, propynyl, and butynyl. The aliphatically unsaturated organic groups in ingredient (A′) may be located at terminal, pendant, or both terminal and pendant positions.

The remaining silicon-bonded organic groups in ingredient (A′) may be monovalent organic groups free of aliphatic unsaturation. These monovalent organic groups may have 1 to 20 carbon atoms, alternatively 1 to 10 carbon atoms, and are exemplified by, but not limited to alkyl groups such as methyl, ethyl, propyl, pentyl, octyl, undecyl, and octadecyl; cycloalkyl groups such as cyclopentyl and cyclohexyl; and aromatic groups such as phenyl, tolyl, xylyl, benzyl, and 2-phenylethyl.

Ingredient (A′) may comprise a polyorganosiloxane of

R¹₂R²SiO(R¹₂SiO)_{d}(R¹R²SiO)ₑSiR¹₂R², Formula (I)

R¹₃SiO(R¹₂SiO)_{f}(R¹R²SiO)_{g}SiR¹₃, or a combination thereof. Formula (II)

In formulae (I) and (II), each R¹ is independently a monovalent organic group free of aliphatic unsaturation and each R² is independently an aliphatically unsaturated organic group. Subscript d has an average value of at least 2, alternatively subscript d may have a value ranging from 2 to 2000. Subscript e may be 0 or a positive number. Alternatively, subscript e may have an average value ranging from 0 to 2000. Subscript f may be 0 or a positive number. Alternatively, subscript f may have an average value ranging from 0 to 2000. Subscript g has an average value of at least 2. Alternatively subscript g may have an average value ranging from 2 to 2000. Suitable monovalent organic groups for R¹ include, but are not limited to, alkyl such as methyl, ethyl, propyl, pentyl, octyl, undecyl, and octadecyl; cycloalkyl such as cyclopentyl and cyclohexyl; and aryl such as phenyl, tolyl, xylyl, benzyl, and 2-phenylethyl. Each R² is independently an aliphatically unsaturated monovalent organic group. R² is exemplified by alkenyl groups such as vinyl, allyl, and butenyl and alkynyl groups such as ethynyl and propynyl.

Ingredient (A′) may comprise polydiorganosiloxanes such as i) dimethylvinylsiloxy-terminated polydimethylsiloxane, ii) dimethylvinylsiloxy-terminated poly(dimethylsiloxane/methylvinylsiloxane), iii) dimethylvinylsiloxy-terminated polymethylvinylsiloxane, iv) trimethylsiloxy-terminated poly(dimethylsiloxane/methylvinylsiloxane), v) trimethylsiloxy-terminated polymethylvinylsiloxane, vi) dimethylvinylsiloxy-terminated poly(dimethylsiloxane/methylphenylsiloxane), vii) dimethylvinylsiloxy-terminated poly(dimethylsiloxane/diphenylsiloxane), viii) phenyl,methyl,vinyl-siloxy-terminated polydimethylsiloxane, ix) dimethylhexenylsiloxy-terminated polydimethylsiloxane, x) dimethylhexenylsiloxy-terminated poly(dimethylsiloxane/methylhexenylsiloxane), xi) dimethylhexenylsiloxy-terminated polymethylhexenylsiloxane, xii) trimethylsiloxy-terminated poly(dimethylsiloxane/methylhexenylsiloxane), xiii) a combination thereof.

Methods of preparing polydiorganosiloxane fluids suitable for use as ingredient (A′), such as hydrolysis and condensation of the corresponding organohalosilanes or equilibration of cyclic polydiorganosiloxanes, are well known in the art.

In addition to the polydiorganosiloxane described above, ingredient (A′) may further comprise a resin such as an MQ resin consisting essentially of R³₃SiO_{1/2} units and SiO_{4/2} units, a TD resin consisting essentially of R³SiO_{3/2} units and R³₂SiO_{2/2} units, an MT resin consisting essentially of R³₃SiO_{1/2} units and R³SiO_{3/2} units, an MTD resin consisting essentially of R³₃SiO_{1/2} units, R³SiO_{3/2} units, and R³₂SiO_{2/2} units, or a combination thereof.

Each R³ is a monovalent organic group. The monovalent organic groups represented by R³ may have 1 to 20 carbon atoms. Examples of monovalent organic groups include, but are not limited to, monovalent hydrocarbon groups and monovalent halogenated hydrocarbon groups. Monovalent hydrocarbon groups include, but are not limited to, alkyl such as methyl, ethyl, propyl, pentyl, octyl, undecyl, and octadecyl; cycloalkyl such as cyclohexyl; alkenyl such as vinyl, allyl, butenyl, and hexenyl; alkynyl such as ethynyl, propynyl, and butynyl; and aryl such as phenyl, tolyl, xylyl, benzyl, and 2-phenylethyl.

The resin may contain an average of 3 to 30 mole percent of aliphatically unsaturated organic groups. The aliphatically unsaturated organic groups may be alkenyl groups, alkynyl groups, or a combination thereof. The mole percent of aliphatically unsaturated organic groups in the resin is the ratio of the number of moles of unsaturated group-containing siloxane units in the resin to the total number of moles of siloxane units in the resin, multiplied by 100.

Methods of preparing resins are well known in the art. For example, resin may be prepared by treating a resin copolymer produced by the silica hydrosol capping process of Daudt, et al. with at least an alkenyl-containing endblocking reagent. The method of Daudt et al., is disclosed in U.S. Pat. No. 2,676,182.

Briefly stated, the method of Daudt, et al. involves reacting a silica hydrosol under acidic conditions with a hydrolyzable triorganosilane such as trimethylchlorosilane, a siloxane such as hexamethyldisiloxane, or mixtures thereof, and recovering a copolymer having M and Q units. The resulting copolymers generally contain from 2 to 5 percent by weight of hydroxyl groups.

The resin, which typically contains less than 2 percent by weight of silicon-bonded hydroxyl groups, may be prepared by reacting the product of Daudt, et al. with an unsaturated organic group-containing endblocking agent and an endblocking agent free of aliphatic unsaturation, in an amount sufficient to provide from 3 to 30 mole percent of unsaturated organic groups in the final product. Examples of endblocking agents include, but are not limited to, silazanes, siloxanes, and silanes. Suitable endblocking agents are known in the art and exemplified in U.S. Pat. Nos. 4,584,355; 4,591,622; and 4,585,836. A single endblocking agent or a mixture of such agents may be used to prepare the resin.

Ingredient (A′) can be one single base polymer or a combination comprising two or more base polymers that differ in at least one of the following properties: structure, viscosity, average molecular weight, siloxane units, and sequence.

### Ingredient (B′) Crosslinker

Ingredient (B′) in the hydrosilylation cure package may be a silane or an organohydrogenpolysiloxane having an average of at least two silicon-bonded hydrogen atoms per molecule. The amount of ingredient (B′) in the hydrosilylation curable composition depends on various factors including the SiH content of ingredient (B′), the unsaturated group content of ingredient (A′), and the properties of the cured product of the composition desired, however, the amount of ingredient (B′) may be sufficient to provide a molar ratio of SiH groups in ingredient (B′) to aliphatically unsaturated organic groups in ingredient (A′) (commonly referred to as the SiH:Vi ratio) ranging from 0.3:1 to 5:1. Ingredient (B′) can be a homopolymer or a copolymer. Ingredient (B′) can have a linear, branched, cyclic, or resinous structure. The silicon-bonded hydrogen atoms in ingredient (B′) can be located at terminal, pendant, or at both terminal and pendant positions.

Ingredient (B′) may comprise siloxane units including, but not limited to, HR⁴₂SiO_{1/2}, R⁴₃SiO_{1/2}, HR⁴SiO_{2/2}, R⁴₂SiO_{2/2}, R⁴SiO_{3/2}, and SiO_{4/2} units. In the preceding formulae, each R⁴ is independently selected from monovalent organic groups free of aliphatic unsaturation.

Ingredient (B′) may comprise a compound of the formula

R⁴₃SiO(R⁴₂SiO)ₕ(R⁴HSiO)ᵢSiR⁴₃, (III)

R⁴₂HSiO(R⁴₂SiO)ⱼ(R⁴HSiO)ₖSiR⁴₂H, or (IV)

a combination thereof.

In formulae (III) and (IV) above, subscript h has an average value ranging from 0 to 2000, subscript i has an average value ranging from 2 to 2000, subscript j has an average value ranging from 0 to 2000, and subscript k has an average value ranging from 0 to 2000. Each R⁹ is independently a monovalent organic group. Suitable monovalent organic groups include alkyl such as methyl, ethyl, propyl, pentyl, octyl, undecyl, and octadecyl; cycloalkyl such as cyclopentyl and cyclohexyl; alkenyl such as vinyl, allyl, butenyl, and hexenyl; alkynyl such as ethynyl, propynyl, and butynyl; and aryl such as phenyl, tolyl, xylyl, benzyl, and 2-phenylethyl.

Ingredient (B′) is exemplified by
a) dimethylhydrogensiloxy-terminated polydimethylsiloxane,
b) dimethylhydrogensiloxy-terminated poly(dimethylsiloxane/methylhydrogensiloxane),
c) dimethylhydrogensiloxy-terminated polymethylhydrogensiloxane,
d) trimethylsiloxy-terminated poly(dimethylsiloxane/methylhydrogensiloxane),
e) trimethylsiloxy-terminated polymethylhydrogensiloxane,
f) a resin consisting essentially of H(CH₃)₂SiO_{1/2} units and SiO_{4/2} units, and
g) a combination thereof.

Ingredient (B′) may be a combination of two or more organohydrogenpolysiloxanes that differ in at least one of the following properties: structure, average molecular weight, viscosity, siloxane units, and sequence. Dimethylhydrogensiloxy-terminated polydimethylsiloxanes having relatively low degrees of polymerization (e.g., DP ranging from 3 to 50) are commonly referred to as chain extenders, and a portion of ingredient (B′) may be a chain extender.

Methods of preparing linear, branched, and cyclic organohydrogenpolysiloxanes suitable for use as ingredient (B′), such as hydrolysis and condensation of organohalosilanes, are well known in the art. Methods of preparing organohydrogenpolysiloxane resins suitable for use as ingredient (B′) are also well known as exemplified in U.S. Pat. Nos. 5,310,843; 4,370,358; and 4,707,531.

### Ingredient (C′) Hydrosilylation Catalyst

Ingredient (C′) of the hydrosilylation curable composition is a hydrosilylation catalyst. Ingredient (C′) is added to the hydrosilylation curable composition in an amount that may range from 0.1 ppm to 1000 ppm, alternatively 1 to 500 ppm, alternatively 2 to 200, alternatively 5 to 150 ppm, by weight of platinum group metal based on the weight of the curable composition.

Suitable hydrosilylation catalysts are known in the art and commercially available. Ingredient (C′) may comprise a platinum group metal selected from platinum, rhodium, ruthenium, palladium, osmium or iridium metal or organometallic compound thereof, or a combination thereof. Ingredient (C′) is exemplified by compounds such as chloroplatinic acid, chloroplatinic acid hexahydrate, platinum dichloride, and complexes of said compounds with low molecular weight organopolysiloxanes or platinum compounds microencapsulated in a matrix or coreshell type structure. Complexes of platinum with low molecular weight organopolysiloxanes include 1,3-diethenyl-1,1,3,3-tetramethyldisiloxane complexes with platinum. These complexes may be microencapsulated in a resin matrix. Alternatively, the catalyst may comprise 1,3-diethenyl-1,1,3,3-tetramethyldisiloxane complex with platinum. When the catalyst is a platinum complex with a low molecular weight organopolysiloxane, the amount of catalyst may range from 0.04 to 0.4% based on the weight of the curable silicone composition.

Suitable hydrosilylation catalysts for ingredient (C′) are described in, for example, U.S. Pat. Nos. 3,159,601; 3,220,972; 3,296,291; 3,419,593; 3,516,946; 3,814,730; 3,989,668; 4,784,879; 5,036,117; and 5,175,325 and EP 0 347 895 B. Microencapsulated hydrosilylation catalysts and methods of preparing them are known in the art, as exemplified in U.S. Pat. No. 4,766,176; and U.S. Pat. No. 5,017,654.

### Peroxide Curable Composition

Alternatively, the peroxide curable composition may comprise: 100 parts by weight of (A″) a base polymer, optionally an amount sufficient to cure the composition of (B″) a crosslinker, and an amount sufficient to accelerate curing of the composition of (C″) a peroxide catalyst, where the ingredients and amounts are selected such that a cured product of the composition may be a silicone rubber.

### Ingredient (A″) Base Polymer

Ingredient (A″) of the peroxide cure package may comprise a polydiorganosiloxane having an average of at least two aliphatically unsaturated organic groups per molecule, such as the polyorganosiloxane described above as ingredient (A′) of the hydrosilylation cure package.

### Optional Ingredient (B″) Crosslinker

Ingredient (B″) is a crosslinker, which may optionally be added to the peroxide curable composition to improve (reduce) compression set of a cured silicone prepared by curing this composition. The amount of ingredient (B″) in the peroxide curable composition depends on various factors including the SiH content of ingredient (B″), the unsaturated group content of ingredient (A″), and the properties of the cured product of the composition desired, however, the amount of ingredient (B″) may be sufficient to provide a molar ratio of SiH groups in ingredient (B″) to aliphatically unsaturated organic groups in ingredient (A″) (commonly referred to as the SiH:Vi ratio) ranging from 0.3:1 to 5:1. The amount of ingredient (B″) in the composition may range from 0 to 15 parts (by weight) per 100 parts by weight of ingredient (A″). Ingredient (B″) may comprise a polydiorganohydrogensiloxane having an average of at least two silicon-bonded hydrogen atoms per molecule. Ingredient (B″) is exemplified by the polydiorganohydrogensiloxanes described as ingredient (B′) in the hydrosilylation curable composition.

### Ingredient (C″) Catalyst

Ingredient (C″) in the peroxide curable composition comprises a peroxide compound. The amount of ingredient (C″) added to the composition depends on the specific peroxide compound selected for ingredient (C″), however, the amount may range from 0.2 to 5 parts (by weight), per 100 parts by weight of ingredient (A″). Examples of peroxide compounds suitable for ingredient (C″) include, but are not limited to 2,4-dichlorobenzoyl peroxide, dicumyl peroxide, and a combination thereof; as well as combinations of such a peroxide with a benzoate compound such as tertiary-butyl perbenzoate. Suitable peroxide curable compositions are known in the art, and are disclosed in, for example, U.S. Pat. No. 4,774,281.

### Ingredient (D) Thermally Conductive Filler

Ingredient (D) is a thermally conductive filler. Ingredient (D) may be both thermally conductive and electrically conductive. Alternatively, ingredient (D) may be thermally conductive and electrically insulating. Ingredient (D) may be selected from aluminum nitride, aluminum oxide, aluminum trihydrate, barium titanate, beryllium oxide, boron nitride, carbon fibers, diamond, graphite, magnesium hydroxide, magnesium oxide, metal particulate, onyx, silicon carbide, tungsten carbide, zinc oxide, and a combination thereof. Ingredient (D) may comprise a metallic filler, an inorganic filler, a meltable filler, or a combination thereof. Metallic fillers include particles of metals and particles of metals having layers on the surfaces of the particles. These layers may be, for example, metal nitride layers or metal oxide layers on the surfaces of the particles. Suitable metallic fillers are exemplified by particles of metals selected from aluminum, copper, gold, nickel, silver, and combinations thereof, and alternatively aluminum. Suitable metallic fillers are further exemplified by particles of the metals listed above having layers on their surfaces selected from aluminum nitride, aluminum oxide, copper oxide, nickel oxide, silver oxide, and combinations thereof. For example, the metallic filler may comprise aluminum particles having aluminum oxide layers on their surfaces.

Inorganic fillers are exemplified by onyx; aluminum trihydrate, metal oxides such as aluminum oxide, beryllium oxide, magnesium oxide, and zinc oxide; nitrides such as aluminum nitride and boron nitride; carbides such as silicon carbide and tungsten carbide; and combinations thereof. Alternatively, inorganic fillers are exemplified by aluminum oxide, zinc oxide, and combinations thereof. Meltable fillers may comprise Bi, Ga, In, Sn, or an alloy thereof. The meltable filler may optionally further comprise Ag, Au, Cd, Cu, Pb, Sb, Zn, or a combination thereof. Examples of suitable meltable fillers include Ga, In—Bi—Sn alloys, Sn—In—Zn alloys, Sn—In—Ag alloys, Sn—Ag—Bi alloys, Sn—Bi—Cu—Ag alloys, Sn—Ag—Cu—Sb alloys, Sn—Ag—Cu alloys, Sn—Ag alloys, Sn—Ag—Cu—Zn alloys, and combinations thereof. The meltable filler may have a melting point ranging from 50° C. to 250° C., alternatively 150° C. to 225° C. The meltable filler may be a eutectic alloy, a non-eutectic alloy, or a pure metal. Meltable fillers are commercially available.

For example, meltable fillers may be obtained from Indium Corporation of America, Utica, N.Y., U.S.A.; Arconium, Providence, R.I., U.S.A.; and AIM Solder, Cranston, R.I., U.S.A. Aluminum fillers are commercially available, for example, from Toyal America, Inc. of Naperville, Ill., U.S.A. and Valimet Inc., of Stockton, Calif., U.S.A. Silver filler is commercially available from Metalor Technologies U.S.A. Corp. of Attleboro, Mass., U.S.A.

Thermally conductive fillers are known in the art and commercially available, see for example, U.S. Pat. No. 6,169,142 (col. 4, lines 7-33). For example, CB-A20S and Al-43-Me are aluminum oxide fillers of differing particle sizes commercially available from Showa-Denko, and AA-04, AA-2, and AA-18 are aluminum oxide fillers commercially available from Sumitomo Chemical Company Zinc oxides, such as zinc oxides having trademarks KADOX® and XX®, are commercially available from Horsehead Corporation of Monaca, Pa., U.S.A.

The shape of the thermally conductive filler particles is not specifically restricted, however, rounded or spherical particles may prevent viscosity increase to an undesirable level upon high loading of the thermally conductive filler in the composition.

Ingredient (D) may be a single thermally conductive filler or a combination of two or more thermally conductive fillers that differ in at least one property such as particle shape, average particle size, particle size distribution, and type of filler. For example, it may be desirable to use a combination of inorganic fillers, such as a first aluminum oxide having a larger average particle size and a second aluminum oxide having a smaller average particle size. Alternatively, it may be desirable, for example, use a combination of an aluminum oxide having a larger average particle size with a zinc oxide having a smaller average particle size. Alternatively, it may be desirable to use combinations of metallic fillers, such as a first aluminum having a larger average particle size and a second aluminum having a smaller average particle size. Alternatively, it may be desirable to use combinations of metallic and inorganic fillers, such as a combination of aluminum and aluminum oxide fillers; a combination of aluminum and zinc oxide fillers; or a combination of aluminum, aluminum oxide, and zinc oxide fillers. Use of a first filler having a larger average particle size and a second filler having a smaller average particle size than the first filler may improve packing efficiency, may reduce viscosity, and may enhance heat transfer.

The average particle size of the thermally conductive filler will depend on various factors including the type of thermally conductive filler selected for ingredient (D) and the exact amount added to the curable composition, as well as the bondline thickness of the device in which the cured product of the composition will be used when the cured product will be used as a TIM. However, the thermally conductive filler may have an average particle size ranging from 0.1 micrometer to 80 micrometers, alternatively 0.1 micrometer to 50 micrometers, and alternatively 0.1 micrometer to 10 micrometers.

The amount of ingredient (D) in the composition depends on various factors including the silicone cure mechanism selected for the composition and the thermally conductive filler selected for ingredient (D). However, the amount of ingredient (D) may range from 30% to 80%, alternatively 50% to 75% by volume of the composition. Without wishing to be bound by theory, it is thought that when the amount of filler is greater than 80%, the composition may crosslink to form a cured silicone with insufficient dimensional integrity for some applications, and when the amount of filler is less than 30%, the cured silicone prepared from the composition may have insufficient thermal conductivity for TIM applications.

### Ingredient (E) Organic Plasticizer

The composition contains an organic plasticizer. Without wishing to be bound by theory, the organic plasticizer may improve the compression set properties of a cured silicone prepared by curing the composition. The plasticizer has an average, per molecule, of at least one group of formula (V).

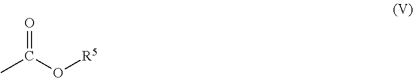

where R⁵ represents a hydrogen atom or a monovalent organic group. Alternatively, R⁵ may represent a branched or linear monovalent hydrocarbon group. The monovalent organic group may be a branched or linear monovalent hydrocarbon group such as an alkyl group of 4 to 15 carbon atoms, alternatively 9 to 12 carbon atoms. Suitable plasticizers may be selected from adipates, carboxylates, phthalates, and combinations thereof.

Alternatively, the plasticizer may have an average, per molecule, of at least two groups of formula (V) bonded to carbon atoms in a cyclic hydrocarbon. The plasticizer may have general formula (VI):

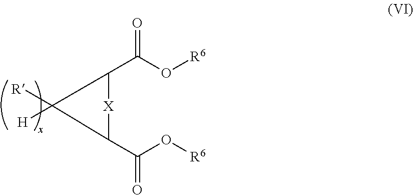

In formula (VI), group X represents a cyclic hydrocarbon group having 3 or more carbon atoms, alternatively 3 to 15 carbon atoms. (Subscript x may have a value ranging from 1 to 12.) Group X may be saturated or aromatic. Each R′ is independently a hydrogen atom or a branched or linear monovalent organic group. The monovalent organic group for R′ may be an alkyl group such as methyl, ethyl, or butyl. Alternatively, the monovalent organic group for R′ may be an ester functional group. Each R⁶ is independently a branched or linear i monovalent hydrocarbon group, such as an alkyl group of 4 to 15 carbon atoms.

Examples of organic plasticizers of formula (VI) may have a formula (VII), (VIII), (IX), or (X) set forth below.

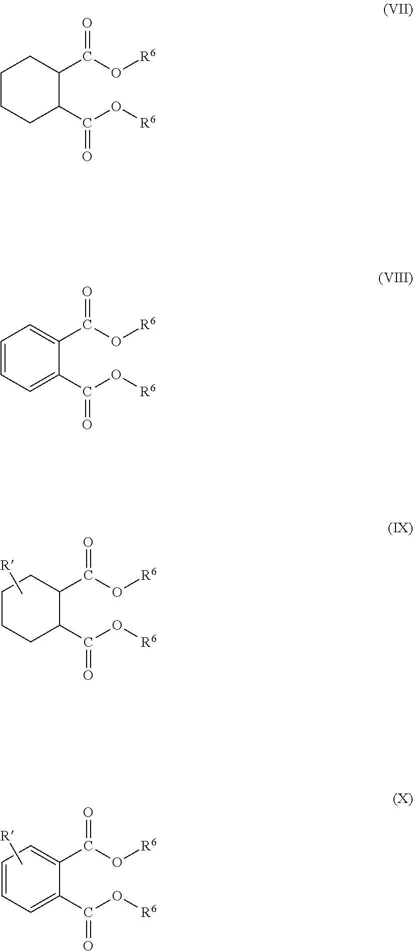

In formulae (VIII), (IX), (X), and (XI), R⁶ is as described above. Formulae (VII) and (VIII) represent the cases where the cycloalkyl group in formula (VII) and the aryl group in formula (VIII) are unsubstituted. Formulae (IX) and (X) show that the cycloalkyl group in formula (IX) and the aryl group in formula (X) may be replaced with organic groups in which one or more of the hydrogen atoms bonded to the member atoms, in the cycloalkyl group of formula (VII) or in the aryl group of formula (VIII), shown is replaced with another monovalent organic group represented by R′. Each R′ may be an alkyl group such as methyl, ethyl, or butyl. Alternatively, the monovalent organic group for R′ may be an ester functional group.

Suitable plasticizers are known in the art and are commercially available. The plasticizer may comprise: bis(2-ethylhexyl)terephthalate; bis(2-ethylhexyl)-1,4-benzenedicarboxylate; 2-ethylhexyl methyl-1,4-benzenedicarboxylate; 1,2 cyclohexanedicarboxylic acid, dinonyl ester, branched and linear; bis(2-propylheptyl)phthalate; diisononyl adipate; trioctyl trimellitate; triethylene glycol bis(2-ethylhexanoate); di(2-ethylhexyl)phthalate; triacetin; bis(2-ethylhexyl)adipate; dimethyl phthalate; diethyl phthalate; dibutyl phthalate; di-2-ethylhexyladipate; 1,2,4-benzenetricarboxylic acid, tris(2-ethylhexyl)ester; a fatty acid ester; and a combination thereof. Alternatively, the plasticizer may be selected from: bis(2-ethylhexyl)terephthalate; bis(2-ethylhexyl)-1,4-benzenedicarboxylate; 2-ethylhexyl methyl-1,4-benzenedicarboxylate; 1,2 cyclohexanedicarboxylic acid, dinonyl ester, branched and linear; bis(2-propylheptyl)phthalate; diisononyl adipate; and a combination thereof. Examples of suitable plasticizers and their commercial sources include those listed below in Table 1.

The amount of plasticizer added to the composition depends on various factors including the type of the plasticizer selected and the other ingredients of the composition. The plasticizer may be soluble in the composition. The plasticizer may be selected such that the plasticizer does not inhibit the curing reaction of the composition. However, the amount of the plasticizer may range from 2 wt % to 50 wt %, alternatively 3 wt % to 25 wt %, based on the combination of base polymer and crosslinker described below. Without wishing to be bound by theory it is thought that less than 2 wt % may be insufficient to improve compression set of a cured silicone prepared by curing the composition, and more than 50 wt % can be insoluble in the composition, resulting in loss of stability or the plasticizer bleeding out of the cured silicone prepared by curing the composition.

TABLE 1

| Product Name | Weight % | Component | CAS Registry No. |
|---|---|---|---|
| Eastman(TM) 425 Plasticizer | 75% | bis(2-ethylhexyl) terephthalate | 6422-86-2 |
| Eastman(TM) 168 Plasticizer | >98% | bis(2-ethylhexyl)-1,4-benzenedicarboxylate | 6422-86-2 |
| | <2% | 2-ethylhexyl methyl-1,4-benzenedicarboxylate | 63468-13-3 |
| Eastman(TM) 168-CA Plasticizer | >97% | bis(2-ethylhexyl)-1,4-benzenedicarboxylate | 6422-86-2 |
| | <2% | 2-ethylhexyl methyl-1,4-benzenedicarboxylate | 63468-13-3 |
| BASF Hexamoll *DINCH | >99.5% | 1,2 cyclohexanedicarboxylic acid, dinonyl ester, | 474919-59-0 |
| | | branched and linear | |
| BASF Palatinol ® DPHP | 99.9% | bis(2-propylheptyl) phthalate or Di-(2-Propyl Heptyl) | 53306-54-0 |
| | | Phthalate | |
| BASF Palamoll ® 652 | 96.0% | PMN00-0611 | 208945-13-5 |
| | 4.0% | diisononyl adipate | 33703-08-1 |
| Eastman 168 Xtreme (TM) | 100% | plasticizer | unknown |
| Plasticizer | | | |
| Eastman(TM) TOTM Plasticize | >99.9% | trioctyl trimellitate | 3319-31-1 |
| Eastman(TM) TEG-EH Plasticizer | 100% | triethylene glycol bis(2-ethylhexanoate) | 94-28-0 |
| Eastman(TM) DOP Plasticizer | 100% | di(2-ethylhexyl) phthalate | 117-81-7 |
| Eastman(TM) Triacetin | 100% | Triacetin | 102-76-1 |
| Eastman(TM) DOA Plasticizer | 100% | bis(2-ethylhexyl) adipate | 103-23-1 |
| Eastman(TM) DOA Plasticizer, | 100% | bis(2-ethylhexyl) adipate | 103-23-1 |
| Kosher | | | |
| Eastman(TM) DMP Plasticizer | 100% | dimethyl phthalate | 131-11-3 |
| Eastman(TM) DEP Plasticizer | 100% | diethyl phthalate | 84-66-2 |
| Eastman(TM) DBP Plasticizer | 100% | dibutyl phthalate | 84-74-2 |
| BASF Plastomoll ® DOA | >99.5% | Di-2-ethylhexyladipate | 103-23-1 |
| BASF Palatinol ® TOTM-I | >99% | 1,2,4-Benzenetricarboxylic acid, tris(2-ethylhexyl) ester | 3319-31-1 |

### Optional Ingredients

The composition may optionally further comprise one or more additional ingredients. The additional ingredient may be selected from (F) a spacer, (G) a reinforcing or extending filler, (H) filler treating agent, (I) an adhesion promoter, (J) a vehicle, (K) a surfactant, (L) a flux agent, (M) an acid acceptor, (N) a stabilizer (e.g., a hydrosilylation cure stabilizer, a heat stabilizer, or a UV stabilizer), and a combination thereof.

### Ingredient (F) Spacer

Ingredient (F) is a spacer. Spacers can comprise organic particles, inorganic particles, or a combination thereof. Spacers can be thermally conductive, electrically conductive, or both. Spacers can have any particle size, e.g., depending on the desired thickness of the interface between the LED mounted circuit board and the heat sink, however, the particle size may range from 100 micrometers to 1000 micrometers, alternatively from 150 micrometers to 300 micrometers. Spacers can comprise monodisperse beads, such as glass or polymer (e.g., polystyrene) beads. Spacers can comprise thermally conductive fillers such as alumina, aluminum nitride, atomized metal powders, boron nitride, copper, and silver. The amount of ingredient (F) depends on various factors including the particle size distribution, pressure to be applied during placement of the curable composition or cured product prepared therefrom, and temperature during placement. However, the composition may contain an amount of ingredient (F) ranging from 0.05% to 2%, alternatively 0.1% to 1%. Ingredient (F) may be added to control bondline thickness of the cured product of the curable composition.

### Ingredient (G) Filler

Ingredient (G) is a reinforcing and/or extending filler. The amount of ingredient (G) in the composition depends on various factors including the materials selected for ingredients (A), (B), (C), (D) and (E) and the end use of the composition. However, the amount of ingredient (G) may range from 0.1 wt % to 10 wt % based on the weight of the composition. Suitable reinforcing and extending fillers are known in the art and are exemplified by precipitated and ground silica, precipitated and ground calcium carbonate, quartz, talc, chopped fiber such as chopped KEVLAR®, or a combination thereof.

### Ingredient (H) Filler Treating Agent

The thermally conductive filler for ingredient (D) and the reinforcing and/or extending filler for ingredient (G) and/or the spacer for ingredient (F), if present, may optionally be surface treated with ingredient (H) a treating agent. Treating agents and treating methods are known in the art, see for example, U.S. Pat. No. 6,169,142 (col. 4, line 42 to col. 5, line 2).

The amount of ingredient (H) may vary depending on various factors including the type and amounts of fillers selected for ingredients (D) and (G) and whether the filler is treated with ingredient (H) in situ or before being combined with other ingredients of the composition. However, the composition may comprise an amount ranging from 0.1% to 2% of ingredient (H).

The ingredient (H) may comprise an alkoxysilane having the formula: R⁸ₘSi(OR⁹)₍₄₋ₘ₎, where subscript m is 1, 2, or 3; alternatively m is 3. Each R⁸ is independently a monovalent organic group, such as a hydrocarbon group of 1 to 50 carbon atoms, alternatively 6 to 18 carbon atoms. R⁸ is exemplified by alkyl groups such as hexyl, octyl, dodecyl, tetradecyl, hexadecyl, and octadecyl; and aromatic groups such as benzyl, phenyl and phenylethyl. R⁸ can be saturated or unsaturated, branched or unbranched, and unsubstituted. R⁸ can be saturated, unbranched, and unsubstituted.

Each R⁹ may be an unsubstituted, saturated hydrocarbon group of 1 to 4 carbon atoms, alternatively 1 to 2 carbon atoms. Alkoxysilanes for ingredient (H) are exemplified by hexyltrimethoxysilane, octyltriethoxysilane, decyltrimethoxysilane, dodecyltrimethoxysilane, tetradecyltrimethoxysilane, phenyltrimethoxysilane, phenylethyltrimethoxysilane, octadecyltrimethoxysilane, octadecyltriethoxysilane, and a combination thereof.

Alkoxy-functional oligosiloxanes can also be used as treatment agents. Alkoxy-functional oligosiloxanes and methods for their preparation are known in the art, see for example, EP 1 101 167 A2. For example, suitable alkoxy-functional oligosiloxanes include those of the formula (R¹²O)ₙSi(OSiR¹⁰₂R¹¹)₍₄₋ₙ₎. In this formula, subscript n is 1, 2, or 3, alternatively n is 3. Each R¹⁰ can be independently selected from saturated and unsaturated monovalent hydrocarbon groups of 1 to 10 carbon atoms. Each R¹¹ can be a saturated or unsaturated monovalent hydrocarbon group having at least 11 carbon atoms. Each R¹² can be an alkyl group.

Metal fillers can be treated with alkylthiols such as octadecyl mercaptan and others, and fatty acids such as oleic acid, stearic acid, titanates, titanate coupling agents, zirconate coupling agents, and a combination thereof.

Treatment agents for alumina or passivated aluminum nitride may include alkoxysilyl functional alkylmethyl polysiloxanes (e.g., partial hydrolysis condensate of R¹³ₒR¹⁴ₚSi(OR¹⁵)₍₄₋ₒ₋ₚ₎ or cohydrolysis condensates or mixtures), or similar materials where the hydrolyzable group may comprise silazane, acyloxy or oximo. In all of these, a group tethered to Si, such as R¹³ in the formula above, is a long chain unsaturated monovalent hydrocarbon or monovalent aromatic-functional hydrocarbon. Each R¹⁴ is independently a monovalent hydrocarbon group, and each R¹⁵ is independently a monovalent hydrocarbon group of 1 to 4 carbon atoms. In the formula above, subscript o is 1, 2, or 3 and subscript p is 0, 1, or 2, with the proviso that the sum o+p is 1, 2, or 3. One skilled in the art could optimize a specific treatment to aid dispersion of the filler without undue experimentation.

### Ingredient (I) Adhesion Promoter

Ingredient (I) is an adhesion promoter. Suitable adhesion promoters may comprise alkoxysilanes of the formula R¹⁶_{q}Si(OR¹⁷)_{(4-q)}, where subscript q is 1, 2, or 3, alternatively q is 3. Each R¹⁶ is independently a monovalent organofunctional group. R¹⁶ can be an epoxyfunctional group such as glycidoxypropyl or (epoxycyclohexyl)ethyl, an amino functional group such as aminoethylaminopropyl or aminopropyl, a methacryloxypropyl, or an unsaturated organic group. Each R¹⁷ is independently an unsubstituted, saturated hydrocarbon group of at least 1 carbon atom. R¹⁷ may have 1 to 4 carbon atoms, alternatively 1 to 2 carbon atoms. R¹⁷ is exemplified by methyl, ethyl, n-propyl, and iso-propyl.

Examples of suitable adhesion promoters include glycidoxypropyltrimethoxysilane and a combination of glycidoxypropyltrimethoxysilane with an aluminum chelate or zirconium chelate. Examples of adhesion promoters for hydrosilylation curable compositions may be found in U.S. Pat. No. 4,087,585 and U.S. Pat. No. 5,194,649. The curable composition may comprise 2% to 5% of adhesion promoter based on the weight of the composition.

### Ingredient (J) Vehicle

Ingredient (J) is a vehicle such as a solvent or diluent. Ingredient (J) can be added during preparation of the composition, for example, to aid mixing and delivery. All or a portion of ingredient (J) may optionally be removed after the composition is prepared.

### Ingredient (K) Surfactant

Ingredient (K) is a surfactant. Suitable surfactants include silicone polyethers, ethylene oxide polymers, propylene oxide polymers, copolymers of ethylene oxide and propylene oxide, other non-ionic surfactants, and combinations thereof. The composition may comprise up to 0.05% of the surfactant based on the weight of the composition.

### Ingredient (L) Flux Agent

Ingredient (L) is a flux agent. The composition may comprise up to 2% of the flux agent based on the weight of the composition. Molecules containing chemically active functional groups such as carboxylic acid and amines can be used as flux agents. Such flux agents can include aliphatic acids such as succinic acid, abietic acid, oleic acid, and adipic acid; aromatic acids such as benzoic acids; aliphatic amines and their derivatives, such as triethanolamine, hydrochloride salts of amines, and hydrobromide salts of amines. Flux agents are known in the art and are commercially available.

### Ingredient (M) Acid Acceptor

Ingredient (M) is an acid acceptor. Suitable acid acceptors include magnesium oxide, calcium oxide, and combinations thereof. The composition may comprise up to 2% of ingredient (M) based on the weight of the composition.

### Ingredient (N) Stabilizer

Ingredient (N) is a stabilizer. Stabilizers for hydrosilylation curable compositions are exemplified by acetylenic alcohols such as methyl butynol, ethynyl cyclohexanol, dimethyl hexynol, and 3,5-dimethyl-1-hexyn-3-ol, 1,1-dimethyl-2-propynyl)oxy)trimethylsilane, methyl(tris(1,1-dimethyl-2-propynyloxy))silane, and a combination thereof; cycloalkenylsiloxanes such as methylvinylcyclosiloxanes exemplified by 1,3,5,7-tetramethyl-1,3,5,7-tetravinylcyclotetrasiloxane, 1,3,5,7-tetramethyl-1,3,5,7-tetrahexenylcyclotetrasiloxane, and a combination thereof; ene-yne compounds such as 3-methyl-3-penten-1-yne, 3,5-dimethyl-3-hexen-1-yne; triazoles such as benzotriazole; phosphines; mercaptans; hydrazines; amines such as tetramethyl ethylenediamine, dialkyl fumarates, dialkenyl fumarates, dialkoxyalkyl fumarates, maleates such as diallyl maleate, and a combination thereof. Alternatively, the stabilizer may comprise an acetylenic alcohol. Suitable hydrosilylation cure stabilizers are disclosed by, for example, U.S. Pat. Nos. 3,445,420; 3,989,667; 4,584,361; and 5,036,117.

The amount of stabilizer added to the composition will depend on the particular stabilizer used and the composition and amount of crosslinker. However, the amount of hydrosilylation cure stabilizer may range from 0.0025% to 0.025% based on the weight of the hydrosilylation curable composition.

One skilled in the art would recognize when selecting ingredients for the thermal management composition described above, there may be overlap between types of ingredients because certain ingredients described herein may have more than one function. For example, certain alkoxysilanes may be useful as filler treating agents and as adhesion promoters, and certain plasticizers such as fatty acid esters may also be useful as filler treating agents. One skilled in the art would be able to distinguish among and select appropriate ingredients, and amounts thereof, based on various factors including the intended use of the composition and whether the composition will be prepared as a one-part or multiple-part composition.

### Method of Preparation of the Composition

The thermal management composition can be formulated that when cured has a thermal conductivity ranging from 0.2 to 7 W/mK. Thermal impedance depend on various factors including the thickness of the cured silicone and the amount and type of the filler selected for ingredient (D).

The thermal management composition can be prepared by a method comprising combining all ingredients by any convenient means such as mixing at ambient or elevated temperature. When the thermal management composition is prepared at elevated temperature, the temperature during preparation is less than the curing temperature of the thermal management composition.

When ingredient (H) is present, the thermal management composition may optionally be prepared by surface treating ingredient (D) (and ingredient (G), if present) with ingredient (H) and thereafter mixing the product thereof with the other ingredients of the thermal management composition.

Alternatively, the thermal management composition may be prepared as a multiple part composition, for example, when ingredient (N) is absent or when the thermal management composition will be stored for a long period of time before use. In the multiple part composition, the crosslinker and catalyst are stored in separate parts, and the parts are combined shortly before use of the composition. For example, a two part curable silicone composition may be prepared by combining ingredients comprising base polymer, catalyst, thermally conductive filler and plasticizer, and one or more additional ingredients in a base part by any convenient means such as mixing. A curing agent part may be prepared by combining ingredients comprising crosslinker, base polymer, thermally conductive filler and plasticizer, and one or more additional ingredients by any convenient means such as mixing. The ingredients may be combined at ambient or elevated temperature, depending on the cure mechanism selected. When a two part curable silicone composition is used, the weight ratio of amounts of base to curing agent may range from 1:1 to 10:1. One skilled in the art would be able to prepare a curable composition without undue experimentation.

### Methods of Use

A method of forming a thermal management composition may comprise:

1) interposing the thermal management composition described above along a thermal path between a heat source and a heat sink, and

2) heating the thermal management composition to a temperature sufficient to cure the composition, thereby forming a cured thermal management composition. In step 1), the thermal management composition can be applied either to the heat source (e.g., an LED mounted circuit board) or the thermal management composition can be applied to the heat sink. Once the thermal management composition is deposited on the LED mounted circuit board, or on the heat sink, the thermal management composition is cured, and the LED mounted circuit board and the heat sink are then secured together. Alternatively, the thermal management composition may be deposited on the LED mounted circuit board or on the heat sink, and the LED mounted circuit board and the heat sink are secured together and then the thermal management composition residing between the LED mounted circuit board and the heat sink is subjected to a cure.

There are two closely related methods for depositing significant quantities of the thermal management composition onto a LED mounted circuit board, or heat sink, or LED mounted circuit board and heat sink in one stroke. The methods generally use the same equipment, although with different settings, the equipment being widely referred to as a “screen printer”, even if actually used only for stencil printing.

Both screen and stencil methods use a squeegee to press the thermal management composition through defined openings, called apertures in an image carrier (the stencil or screen) and onto the LED mounted circuit board, or heat sink, or LED mounted circuit board and heat sink. It is the carrier that determines the pattern and also meters the amount of thermal management composition deposited. The key difference between the processes is that in stencil printing, the image is a set of open apertures in a solid foil and in screen printing, the apertures are in a polymer film supported and actually filled by a fine mesh.

In screen printing and stencil printing, either an automatic or manual printing machine can be used to hold the screen or stencil frame in place. The thermal management composition is then dispensed on to the screen or stencil by means of a spatula full of the thermal management composition directly from a container or by means of a pneumatic dispense from a cartridge or tube. Once the thermal management composition is applied to the screen or stencil, a blade comes into contact with the screen or stencil surface and draws the thermal management composition across the screen or stencil applying enough pressure to push the thermal management composition through the open apertures of the screen or stencil thus depositing the thermal management composition on to the LED mounted circuit board or heat sink as a pattern of the screen or stencil frame. The LED mounted circuit board or heat sink is mounted underneath the screen or stencil frame. In the case of an automatic printing system the blade pressure, draw speed, and stroke length parameters are controlled by the user interface inputs. In the case manual printing the blade and thermal management composition are drawn by hand across the screen or stencil open apertures which transfers material on to the surface of the LED mounted circuit board or the heat sink in similar manner similar to automatic printing. For manual printing, the operator controls the printing parameters such as blade/squeegee pressure, draw speed, and stroke length. Manual printing is a low cost method for screen or stencil printing which is labor intensive but requires little capital investment

### Blades

The most common blades used for screen and stencil printing are either metal or polymer. Metal blades are typically made from stainless steel. The polymer blades, which are commonly called squeegees, are typically made from polyurethane. Squeegees are available in hardness from 60 to 90 shore A. Either metal blades or polymer squeegee blades can be machined or cut to fit into specific mounting equipment, in the case of automatic printing, or can be cut to fit into a simple holder/handle for manual printing. Depending on the print type of pattern being deposited, typically metal blades are used with stencils, since stencils are more durable and polymer squeegees are used with screens since they are more delicate.

### Screens

Printing screens consist of a woven wire mesh supported by a metal frame. The screen mesh can be made from stainless steel wire or also polymer threads with polyester and nylon being common The screen wire mesh is adhered to the metal frame with an adhesive under high tension. Screen wire mesh number corresponds to the number of wire threads per inch. For screen printing of thermal management compositions, screens of 25 to 100 mesh can be used depending on the particular thermal management composition, however 60 to 80 are more common. For creating a screen pattern, the entire screen is coated with a polymer emulsion that coats and plugs up the mesh openings, the openings between the wire. A lithography process is then used to transfer a deposit of the thermal management composition onto the LED or the heat sink. In general, controlling thermal management composition print thickness via screen printing can be controlled by several factors, such as mesh weave thickness, weave wire diameter, and back side emulsion coating build up.

### Stencils

Stencils are typically a metal sheet or foil adhered to and supported by a metal frame. A stencil pattern can be made in the foil by a variety of means such as electoral form, chemical etching or laser drilling. Wire sawing and water jetting can also be used for to make course patterns. For stencil printing thermal management composition, stencils foils from 25 micron to 500 micron can be used however 100 microns to 300 micron are most common. Thinner stencil foils, of less than 100 micron, can be more fragile and susceptible to damage. Foils over 300 micron can produce an undesirable edge effect when printing. In general controlling thermal management composition print thickness via stencil printing can be controlled by the stencil foil thickness.

For both screen and stencil printing, thermal management composition print thickness can also be electoral form affected by equipment or manual print parameters such as blade type, blade pressure, blade speed, blade angle, and blade tip shape, as well as others. The thermal management composition rheology and characteristics must also be considered.

Besides screen and stencil printing, there are other ways to dispense thermal management compositions. Other printing methods include gravure and offset printing. Methods for dispensing thermal management compositions include pneumatic or mechanical dispensing. Jetting or pin transfer and spraying are also conceivable. Of course simple tube or syringe dispense as well as manual spreading with a spatula applicator are doable.

Once either the LED mounted circuit board or heat sink have a deposit of the thermal management composition, the LED mounted circuit board and heat sink are joined together. The thermal management composition may be immediately cured or may be shipped to a customer where the curing occurs on the site of the customer.

The above procedures are means for placing a thermal management composition on either the LED mounted circuit board or heat sink. Alternatively, the thermal management composition may also be applied to a metallic sheet in the same manner as applied to the LED mounted circuit board or heat sink. After the deposition, the thermal management composition may be immediately cured and mounted later to either the LED mounted circuit board or heat sink.

### EXAMPLES

A two-part thermal management composition was prepared by mixing equal parts of Part A and Part B. The following components were mixed together to form Part A.

Part A

| Component | Amount | |
|---|---|---|
| Vinyl terminated linear dimethylsiloxane polymer with a | 8.505 | parts |
| viscosity of 75 cSt and a vinyl content of 1.35% | | |
| n-octyl trimethoxy silane filler treating agent | 0.512 | |
| trimethoxy silane terminated dimethylsilioxane treating | 0.450 | |
| agent of structure | | |
| (CH₃)₃Si0—{(CH₃)₂Si0}₁₁₀—Si(OCH₃)₃ | | |
| Alumina filler with average particle size of 35 μm | 45.244 | |
| Alumina filler with average particle size of 2 μm | 45.244 | |
| vinyl polymer diluted platinum complex of 1,3-diethenyl- | 0.045 | |
| 1,1,3,3-tetramethyldisiloxane where the Pt level is about | | |
| 9000 ppm | | |
| Total | 100.000 | |

For Part A, all the components except the platinum catalyst in silicone fluid were added to a Ross mixer and mixed for 60 minutes. The contents were then heated using steam heat, mixed at a vacuum of 635 millimeters mercury and at a temperature of 140° C. and held for 30 minutes. The vacuum was broken, the steam was turned off, cooling water was turned on, and the contents were mixed for 10 minutes during the cool down. The platinum catalyst in silicone fluid was added and the contents were mixed an additional 15 minutes.

The following components were mixed together to form Part B.

Part B

| Component | Amount | |
|---|---|---|
| Vinyl terminated linear dimethylsiloxane polymer with a | 6.595 | parts |
| viscosity of 75 cSt and a vinyl content of 1.35% | | |
| n-octyl trimethoxy silane filler treating agent | 0.512 | |
| trimethoxy silane terminated dimethylsilioxane treating | 0.450 | |
| agent of structure | | |
| (CH₃)₃Si0—{(CH₃)₂Si0}₁₁₀—Si(OCH₃)₃ | | |
| Alumina filler with average particle size of 35 μm | 45.244 | |
| Alumina filler with average particle size of 2 μm | 45.244 | |
| 3,5-dimethyl-1-hexyn-3-ol | 0.01 | |
| Trimethyl terminated dimethylhydrogenmethylsiloxane | 0.633 | |
| crosslinker | | |
| dimethylhydrogen terminated dimethylsiloxane chain | 0.93 | |
| extender | | |
| Carbon black pigment in silicone | 0.382 | |
| Total | 100.000 | |

For Part B, the first five components were added to a vessel and were combined in a Ross mixer and mixed for 60 minutes. The contents were then heated using steam heat, mixed at a vacuum of 635 millimeters mercury and at a temperature of 140° C. and held for 30 minutes. The vacuum was broken, the steam was turned off, cooling water was turned on, and the contents were mixed for 10 minutes during the cool down. The four remaining components were added and the contents were mixed an additional 15 minutes.

### Measurement of Thermal Properties.

Thermal resistance was measured by using a Guarded Hot Plate technique based on ASTM D5470. This instrument measures the thermal resistance in cm²° C./W and bondline thickness in mm as a function of applied pressure (psi)

Equal parts of Part A and Part B were mixed in a container. An aliquot of material was removed and placed on the copper probes on a guarded hot plate instrument. The top probe was lowered to set a gap at 0.25 mm and the material was cured at 70° C. for one hour while held between the copper probes. This is indicative of a cure-in-place option. After cure, the temperature is set to 50° C. and all measurements at different applied pressure are recorded after the instrument attained steady state conditions. The results are in Table 2.

TABLE 2

| | Bondline Thickness | Thermal Resistance |
|---|---|---|
| Applied Pressure (psi) | (mm) | cm² ° C./W |
| 0 | 0.250 | 1.044 |
| 10 | 0.200 | 0.666 |
| 20 | 0.180 | 0.594 |
| 40 | 0.162 | 0.531 |
| 50 | 0.157 | 0.514 |
| 75 | 0.150 | 0.476 |

A thermal pad obtained from a LED rear tail light fixture was tested for thermal performance under similar temperature and applied pressure conditions. The results are in Table 3.

TABLE 3

| | Bondline Thickness | Thermal Resistance |
|---|---|---|
| Applied Pressure (psi) | (mm) | cm² ° C./W |
| 0 | | |
| 10 | 0.343 | 4.650 |
| 20 | 0.344 | 4.608 |
| 40 | 0.344 | 4.517 |
| 50 | 0.344 | 4.485 |
| 75 | 0.343 | 4.382 |

A thermal pad obtained from a LED auxiliary light fixture was tested for thermal performance under similar temperature and applied pressure conditions. The results are in Table 4.

TABLE 4

| | Bondline Thickness | Thermal Resistance |
|---|---|---|
| Applied Pressure (psi) | (mm) | cm² ° C./W |
| 0 | | |
| 10 | 0.370 | 2.393 |
| 20 | 0.369 | 2.324 |
| 40 | 0.370 | 2.226 |
| 50 | 0.369 | 2.208 |
| 75 | 0.368 | 2.159 |

While the invention has been explained in relation to its preferred embodiments, it is to be understood that various modifications thereof will become apparent to those skilled in the art upon reading the description. Therefore, it is to be understood that the invention disclosed herein is intended to cover such modifications as fall within the scope of the appended claims.

1. A method for applying a thermal management composition between an LED mounted circuit board and a heat sink, where the LED mounted circuit board comprises a substrate having a first surface with at least one LED mounted thereto and a second surface opposite the first surface, the method comprising the steps of;
(a) applying a deposit of a thermal management composition onto either the second surface of the LED mounted circuit board or onto a surface of the heat sink, through a deposition tool having at least one aperture, where the at least one aperture has a perimeter surrounded by sidewalls, where the sidewalls have heights, where the heights are reduced around at least a portion of the perimeter of the apertures on the deposition tool as compared to the average height of the deposition tool and
(b) securing the LED mounted circuit board and the heat sink wherein the thermal management composition resides between the second surface of the LED mounted circuit board and the surface of the heat sink.

2. The method of claim 1, where the deposition tool is a down step stencil and step (a) is performed by stencil printing.

3. The method of claim 1, where the deposition tool is a screen having plurality of apertures, each aperture being surrounded by sidewalls having heights, and where the heights of the sidewalls are reduced around at least a portion of a perimeter of each aperture on the screen as compared to average thickness of the screen, and step (a) is performed by screen printing.

4. The method of claim 1, wherein the thermal management composition is a silicone composition comprising;
(A) a polyorganosiloxane base polymer having an average per molecule of at least two aliphatically unsaturated organic groups,
optionally (B) a crosslinker having an average per molecule of at least two silicon bonded hydrogen atoms,
(C) a catalyst selected from hydrosilylation reaction catalyst and peroxide cure catalysts,
(D) a thermally conductive filler, and
(E) an organic plasticizer soluble in ingredient (A), which does not inhibit curing of the composition, with the proviso that when the catalyst is a hydrosilylation reaction catalyst, then ingredient (B) is present.

5. The method of claim 1, where ingredient (D) comprises: aluminum nitride, aluminum oxide, aluminum trihydrate, barium titanate, beryllium oxide, boron nitride, carbon fibers, diamond, graphite, magnesium hydroxide, magnesium oxide, metal particulate, onyx, silicon carbide, tungsten carbide, zinc oxide, and a combination thereof.

6. The method of claim 1, where ingredient (E) has an average, per molecule, of at least one group of formula 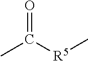
where R⁵ represents a hydrogen atom or a monovalent organic group.

7. The method of claim 1, where ingredient (E) has a formula: 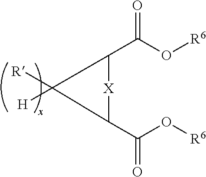
where X represents a cyclic hydrocarbon group, subscript x has a value ranging from 3 to 15, each R⁶ is independently a branched or linear monovalent hydrocarbon group, and each R′ is independently a branched or linear hydrocarbon atom or a monovalent organic group.

8. The method of claim 1, where ingredient (E) is selected from bis(2-ethylhexyl)terephthalate; bis(2-ethylhexyl)-1,4-benzenedicarboxylate; 2-ethylhexyl methyl-1,4-benzenedicarboxylate; 1,2 cyclohexanedicarboxylic acid, dinonyl ester, branched and linear; bis(2-propylheptyl)phthalate or di-(2-propyl heptyl)phthalate; diisononyl adipate; trioctyl trimellitate; triethylene glycol bis(2-ethylhexanoate); diethylene glycol dibenzoate; 1,1,3-tris(2-methyl-4-hydroxy-5-tert-butylphenyl)butane; di(2-ethylhexyl)phthalate; bis(2-ethylhexyl)adipate; dimethyl phthalate; diethyl phthalate; dibutyl phthalate; di-2-ethylhexyladipate; 1,2,4-benzenetricarboxylic acid, tris(2-ethylhexyl)ester; trioctyl trimellitate; triethylene glycol bis(2-ethylhexanoate); bis(2-ethylhexyl)terephthalate; diethylene glycol dibenzoate; 1,1,3-tris(2-methyl-4-hydroxy-5-tert-butylphenyl)butane; 1,2,3-triacetoxypropane; a fatty acid ester; and a combination thereof.

9. The method of claim 1, further comprising: an additional ingredient selected from (F) a spacer, (G) a reinforcing or extending filler, (H) filler treating agent, (I) an adhesion promoter, (J) a vehicle, (K) a surfactant, (L) a flux agent, (M) an acid acceptor, (N) a stabilizer, and a combination thereof.

10. The method of claim 1, wherein the thermal management composition is cured.

11. The method of claim 1 wherein the thermal management composition is cured before step (b).

12. The method of claim 1 wherein the thermal management composition is cured after step (b).
